(19) United States
(12) Patent Application Publication
(10) Pub. No.: US 2014/0290737 A1
(43) Pub. Date: Oct. 2, 2014

(54) THIN FILM VLS SEMICONDUCTOR GROWTH PROCESS

(71) Applicants: Ali Javey, Lafayette, CA (US); Zhibin Yu, Berkeley, CA (US); Rehan Kapadia, Berkeley, CA (US)

(72) Inventors: Ali Javey, Lafayette, CA (US); Zhibin Yu, Berkeley, CA (US); Rehan Kapadia, Berkeley, CA (US)

(73) Assignee: THE REGENTS OF THE UNIVERSITY OF CALIFORNIA, Oakland, CA (US)

(21) Appl. No.: 14/243,586

(22) Filed: Apr. 2, 2014

Related U.S. Application Data
(60) Provisional application No. 61/807,688, filed on Apr. 2, 2013.
(60) Provisional application No. 61/886,546, filed on Oct. 3, 2013.

(51) Int. Cl. H01L 31/0368; H01L 31/0304; H01L 31/18

(52) U.S. Cl. CPC H01L 31/0368; H01L 31/184; H01L 31/0304
USPC 136/256; 438/93

(57) ABSTRACT

A composition comprising a substrate, a polycrystalline III-V semiconductor layer, and an oxide layer disposed above the polycrystalline III-V semiconductor layer is described. A growth method that enables fabrication of continuous thin films of polycrystalline indium phosphide (InP) directly on metal foils is described. The method describes the deposition of an indium (In) thin film (up to 20 microns thick) directly on molybedenum (Mo) foil, followed by the deposition of a thin oxide capping layer (up to 1 micron thick). This capping layer prevents dewetting of the In from the substrate during subsequent high temperature processing steps. The Mo/In/Capping Layer stack is then heated in the presence of phosphorous precursors, causing supersaturation of the liquid indium with phosphorous, followed by precipitation of InP. These polycrystalline III-V films have grain sizes 100-200 microns, minority carrier lifetimes >2 ns and hall mobilities of 500 cm̂2/V-s.

### CROSS REFERENCE TO RELATED APPLICATIONS

This United States Patent Application claims priority to U.S. Provisional Application Ser. No. 61/807,688 filed Apr. 2, 2013, and U.S. Provisional Application Ser. No. 61/886,546 filed Oct. 3, 2013,which applications are incorporated herein by reference as if fully set forth in their entirety.

### STATEMENT OF GOVERNMENTAL SUPPORT

The invention described and claimed herein was made in part utilizing funds supplied by the U.S. Department of Energy under Contract No. DE-AC02-05CH11231 between the U.S. Department of Energy and the Regents of the University of California for the management and operation of the Lawrence Berkeley National Laboratory. The government has certain rights in this invention.

### BACKGROUND OF THE INVENTION

1. Field of the Invention

The present invention relates to the field of Photovoltaic materials and devices.

2. Related Art

Photovoltaic devices fabricated from III-V semiconductors offer the highest efficiencies of all classes of materials available, a direct result of the high external luminescence efficiencies of III-V's. However, until recently, growth of high quality III-V's has required expensive epitaxial substrates and metal-organic chemical vapor deposition (MOCVD) processes, offering significant scaling challenges, and relegating high-efficiency III-V devices to niche applications.

### BRIEF DESCRIPTION OF THE DRAWINGS

The foregoing aspects and others will be readily appreciated by the skilled artisan from the following description of illustrative embodiments when read in conjunction with the accompanying drawings.

FIG. 1 Illustrates a growth technique and resulting InP films. a, Schematic view of the thin-film VLS growth technique for planar and textured InP films. b, 30° tilt view SEM of planar InP film on Mo foil, showing the InP surface, cross-section, and the Mo foil surface. c, Tilt view SEM image of contoured InP grown via pre-texturing the Indium film.

FIG. 2 Illustrates a structural characterization. a, XRD spectrum of an InP film grown at 750° C. b, EBSD image of the backside of a peeled off TF-VLS InP film, indicating large grain sizes of ˜10-100 μm. c, Top-view SEM image of InP peeled off from Mo foil, partially etched in 1% HCl to highlight grain boundaries.

FIG. 3 Illustrates a growth schematic. a, Qualitative diagram of the TF-VLS growth process, showing the phosphorous vapor diffusing through the cap layer, initial InP nucleus, and phosphorus concentration [P] as a function of distance from the nucleus. The depletion zone is defined as the area where [P]<[P]_{Sat}. b, SEM images of the growth of the InP films. Initially, separate InP nuclei/islands form, followed by growth outwards in a dendritic fashion. Finally, separate InP islands converge together and growth completes as all In turns into InP.

FIG. 4 Illustrates an 0ptoelectronic characterization. a, Mobility and carrier concentrations as a function of growth temperature obtained from Hall measurements carried out on peeled off InP films. b, Steady state photoluminescence characterization of a TF-VLS InP film grown at 750° C. (x) and a similarly doped single-crystal wafer as a reference (y). c, Representative TRPL curve for a TF-VLS InP sample grown at 750° C. The dashed line represents 1/e of the initial peak intensity. d, Average time-resolved photoluminescence lifetimes as a function of InP growth temperature. All measurements were performed at room temperature.

FIG. 5 Illustrates a luminescence yield. a, Measured external luminescence efficiency and extracted internal luminescence efficiency as a function of growth temperature. b, Optically measured “I-V” curves obtained from external luminescence efficiency measurements. Here, Suns represents the intensity of the absorbed laser light (1-sun=100 mW/cm²), and corresponds to the photogenerated current level. The quasi-Fermi level splitting (ΔE_{F}) represents the resulting V_{OC} that would occur to balance the photogenerated current.

FIG. 6 Illustrates a schematic of TF-VLS process for InP growth on (a) bare Mo foil, and (b) Mo foil coated with a 50nm-thick MoOₓ nucleation promoter layer.

FIG. 7 Illustrates a substrate effects on nucleation density. False color optical microscope images of InP nucleation and growth on (a) a bare Mo foil substrate and (b) a Mo/MoOₓ substrate. Here, the InP films are partially grown by limiting the growth time to clearly depict the nucleation events.

FIG. 8 Illustrates a patterned nucleation. (a1) Schematic of a Mo foil with a hexagonal MoOₓ dots as the nucleation sites. Center-to-center pitch, s, between the MoOₓ pattern is varied between 0.1 mm to 1 mm. (a2) In/SiOₓ stacks are subsequently evaporated on the patterned Mo/MoOₓ substrate. (a3) An optical image of ˜1 cm×0.5 cm substrate with 0.25 mm MoOx pitch after partial InP growth, clearly demonstrating large area control over nuclei position. b1-4) Optical images of partially grown InP on patterned Mo/MoOx substrates with MoOₓ pitch of 0.1 mm (b1), 0.25 mm (b2), 0.5 mm (b3), and 1 mm (b4).

FIG. 9 Illustrates a theory of deterministic nucleation. (a) Schematic of a Mo/MoOₓ patterned substrate with inter nucleation promoter spacing, s. Representation of a phosphorous depletion zone with diameter, l_{dep} is marked on the schematic. When l_{dep}>s, majority of InP crystals nucleate selectively on MoOₓ sites and not the bare Mo foil. b) A plot of calculated nucleation density, N_{Total}, on patterned substrates for different s values. c) Comparison between experimentally measured and calculated nucleation density as a function of s.

### DETAILED DESCRIPTION

In the discussions that follow, various process steps may or may not be described using certain types of manufacturing equipment, along with certain process parameters. It is to be appreciated that other types of equipment can be used, with different process parameters employed, and that some of the steps may be performed in other manufacturing equipment without departing from the scope of this invention. Furthermore, different process parameters or manufacturing equipment could be substituted for those described herein without departing from the scope of the invention.

These and other details and advantages of the present invention will become more fully apparent from the following description taken in conjunction with the accompanying drawings.

III-V photovoltaics (PVs) have demonstrated the highest power conversion efficiencies for both single- and multi-junction cells. However, expensive epitaxial growth substrates, low precursor utilization rates, long growth times, and large equipment investments restrict applications to concentrated and space photovoltaics (PVs). Various embodiments demonstrate the first thin-film (TF) vapor-liquid-solid (VLS), or TF-VLS, growth of high-quality III-V thin-films on metal foils as a promising platform for large-area terrestrial PVs overcoming the above obstacles. We demonstrate 1-3 μm thick InP thin-films on Mo foils with ultra-large grain size up to 100 μm, which is ˜100 times larger than those obtained by conventional growth processes. The films exhibit electron mobilities as high as 500 cm²/V-s and minority carrier lifetimes as long as 2.5 ns. Furthermore, under 1-sun equivalent illumination, photoluminescence efficiency measurements indicate that an open circuit voltage of up to 930 mV can be achieved with our films, only 40 mV lower than what we measure on a single crystal reference wafer.

Embodiments of the invention extend to all thin-film vapor-liquid-solid (VLS) growth (TF-VLS) wherein the diffusion of V group vapor through a capping layer and dissolution in the liquid III group results in the precipitation of solid III-V crystals as predicted by the III-V phase diagrams.

Embodiments of the invention extend to all polycrystalline III-V semiconductor thin films comprising Indium Phosphide (InP), Indium Arsenide (InAs), Indium Nitride (InN), Indium Antimonide (InSb), Gallium Phosphide (GaP), Gallium Arsenide (GaAs), Gallium Nitride (GaN), Gallium Antimonide (GaSb), Boron Nitride (BN), Boron Phosphide (BP), Boron Arsenide (BAs), Aluminum Nitride (AlN), Aluminum Phosphide (AlP), Aluminum Arsenide (AlAs), Aluminum Antimonide (AlSb).

The growth of semiconductor nanowires (NWs) via the VLS growth mode and the epitaxial layer transfer of semiconductors has proven to be very versatile, yielding a wide variety of materials on a multitude of substrates with excellent optoelectronic properties. VLS-grown NWs exhibit circular or faceted cross-sections, depending on the surface energy constraints of the nucleation seed on the substrate. Shape- and geometry-controlled nanowire growth using tubular templates has also been reported. Here, by utilizing a planar reaction template that (i) prevents dewetting of the growth seed from the substrate, and (ii) is permeable to the vapor phase, the VLS growth technique is extended to thin film geometries for the first time. InP is chosen as a prototypical model system to demonstrate the TF-VLS growth process as it not only has a near-optimal band gap for a single junction PV device, but is reported to have a low unpassivated surface recombination velocity, making it a promising material system for polycrystalline films-based optoelectronics. We show that large grain (up to 100 μm), continuous, polycrystalline InP thin films are readily grown on Mo foils within a large growth parameter window, with optical and electronic properties approaching those of similarly-doped, single-crystalline InP.

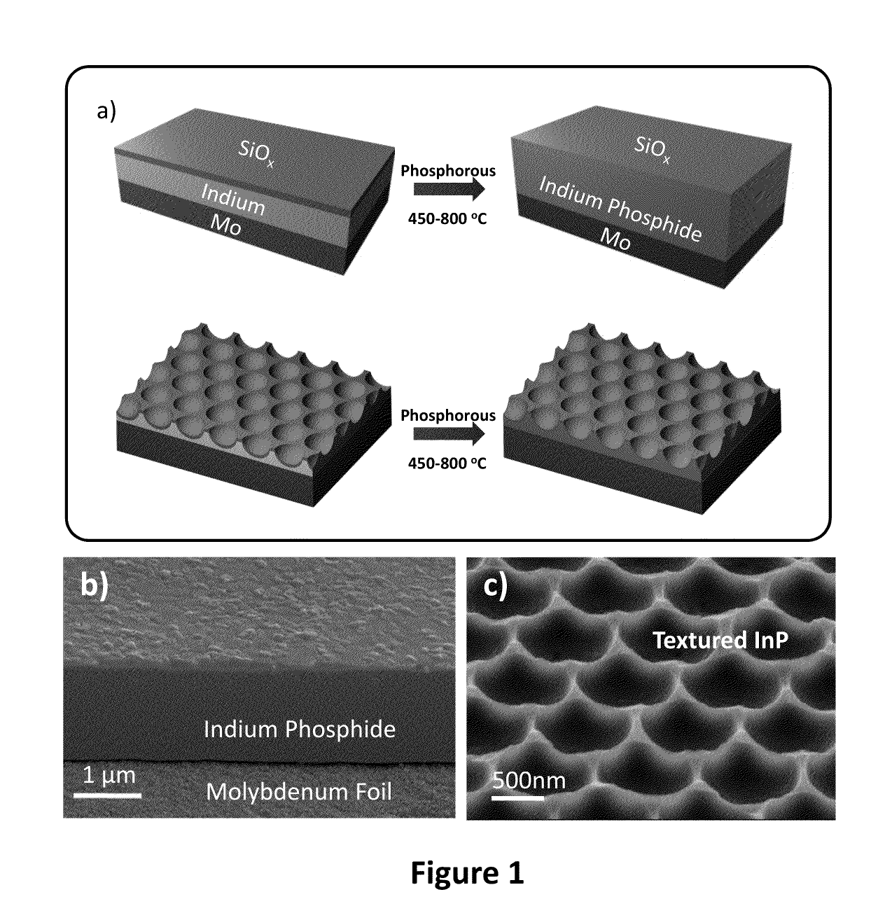

The TF-VLS process is schematically illustrated in FIG. 1a. Indium films (tunable thickness of 0.2-2 μm) are deposited on electropolished molybdenum foils (thickness of ˜25 μm) by either electron-beam (e-beam) evaporation or electroplating, followed by e-beam evaporation of a 50 nm silicon oxide (SiOₓ) cap. The Mo/In/SiOₓ stack is then heated in hydrogen to a growth temperature of 450-800° C., which is above the melting point of indium (˜157° C.). The thin SiOₓ capping layer enables the liquid indium to maintain a planar geometry by preventing it from dewetting. After temperature stabilization, phosphorous vapor is introduced into the chamber, either by PH₃ gas or a heated red phosphorous solid source. The diffusion of phosphorous vapor through the capping layer and dissolution in the liquid indium results in the precipitation of solid InP crystals as predicted by the indium-phosphorus phase diagram. This process closely resembles the self-catalyzed VLS growth of nanowires, but instead produces continuous polycrystalline thin films. FIG. 1b shows a tilt-view cross-sectional scanning electron microscope (SEM) image of a TF-VLS InP film on Mo foil. This image is representative of the film across the growth substrate. The as-grown InP film thickness is roughly double the original indium thickness, matching the expected volume expansion from In to InP and implying near unit utilization of the indium film.

Interestingly, the morphology of the grown InP films can be tuned by the morphology of the starting In film and its corresponding template. As an example, an evaporated indium thin film was coated with closely packed silica beads (˜1 μm in diameter) through a Langmuir-Blodgett (LB) process (see Methods) followed by a mechanical press to embed the beads into the indium film. After subsequent capping by SiOₓ and phosphorization, a nanotextured InP thin film with a hemispherical morphology was obtained (FIG. 1c). The ability to readily control the shape and morphology of the semiconductor film presents a unique feature of the TF-VLS process with important implications for light management and carrier collection in future devices.

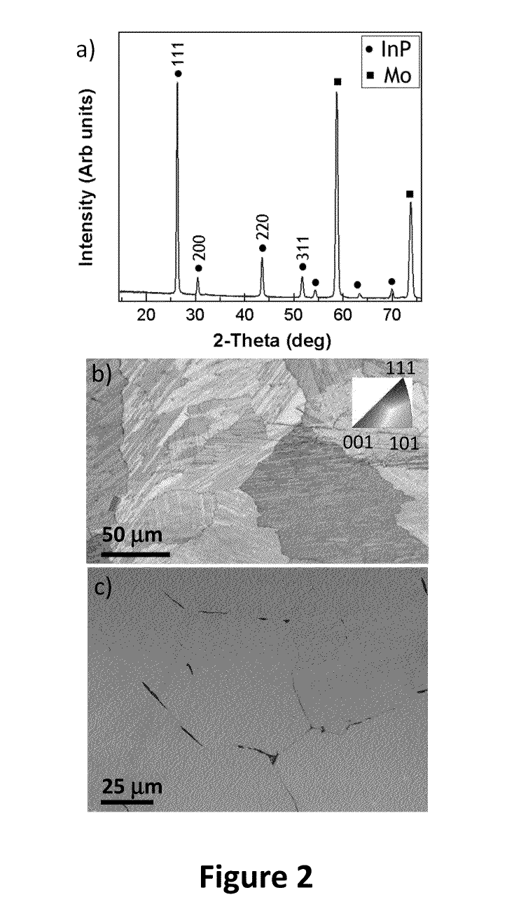

The structural characteristics of the TF-VLS InP were probed by x-ray diffraction (XRD), electron backscatter diffraction (EBSD) and SEM. Both as-grown InP films on Mo and free standing InP films, which were obtained by peeling off the InP layer from the substrate, were examined. XRD analysis (FIG. 2a) establishes three points. First, the films are zinc blended InP. Second, the lack of indium peaks indicates that, to the detection limit of the XRD, the film has turned entirely into InP. Third, the films are polycrystalline and slightly textured as evident by the larger 111 peak intensity as compared to that of 200. EBSD mapping of the InP films was used to determine the grain size. The maps (FIG. 2b) show that the grain sizes vary between 10 μm to greater than 100 μm, despite a film thickness of ˜3 μm. These grains are 10-100 times larger than those previously reported for vapor phase growth of InP thin films on metal foils using metal organic chemical vapor deposition (MOCVD) and close spaced sublimation. The large crystal grain size obtained with TF-VLS leads to excellent optoelectronic properties as discussed in detail below. A plan view SEM image is shown in FIG. 2c; faceted edges of the grains are visible, providing further evidence of the large grain size.

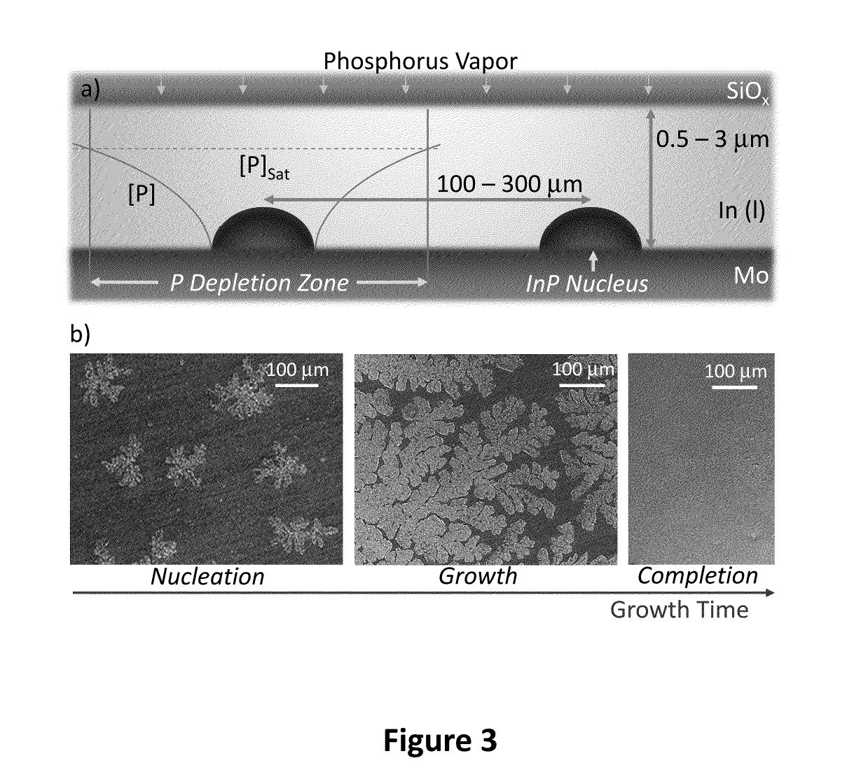

Important features of the TF-VLS growth process are highlighted through a qualitative model (FIG. 3a). The process involves P diffusion through the SiOₓ cap into the liquid indium film, increasing the P concentration, [P], until the concentration slightly exceeds saturation, [P]_{Sat}, enabling nucleation of the solid InP phase on the Mo substrate. It should be noted that InP does not nucleate on the SiOₓ surface because of the high surface energy. Once InP nuclei are formed, they grow via diffusion of nearby P to the In/InP interface, and subsequent incorporation into the solid phase. This diffusion/incorporation process creates a depletion zone near each nucleus, limiting subsequent nucleation events allowing large grain sizes. Growth continues until the entire In film becomes InP (FIG. 3b).

A simple model helps to identify the factors that determine the density of nuclei (see Supplementary Information for details). The model suggests that the number density of nuclei scales as (Fh⁴/D)^{α}, where F is the flux of P into the liquid indium, D is the diffusivity of P within the liquid phase, h is the initial thickness of the indium film, and α is a positive constant less than one related to the critical nucleus size. Based on this simple scaling law, the key to producing a small number of nuclei and thus large grains is to insure that the flux of the incoming P is slow in comparison to the rate at which P diffuses within the liquid phase. Experimentally, the capping layer limits the flux of incoming P as the solid phase diffusivity through the SiOₓ cap (estimated to be ˜10⁻¹² cm²/s at 750° C.) is orders of magnitude lower than that in liquid indium (D˜1.2×10⁻⁴ cm²/s). When phosphorization of indium without the SiOₓ cap is performed, grain size is drastically reduced to ˜1 μm—an observation that supports the model and highlights the importance of the cap. FIG. 3b shows SEM images at various stages of the film growth (i.e. different growth times). Starting with separate InP nuclei formation, spaced ˜100-300 μm apart, the separate islands begin to converge, followed by the completion of film growth. The dendritic morphology is indicative of the rapid diffusion of phosphorous towards the nuclei relative to the rate at which the solid phase relaxes towards its equilibrium shape. These data further support the proposed growth mechanism and model.

Next, we focus on the detailed electrical and optical characterization of InP thin films (˜3 μm in thickness) as a function of growth temperature (T_{Growth}=450-800° C.). After growth, the SiOₓ cap was etched away in HF. Surface cleaning and passivation was then carried out by consecutive 30 second treatments of 1% HCl and 1% HNO₃. The HCl treatment removes the native oxide, while the HNO₃ treatment results in a dense surface oxide layer which is previously shown to improve the surface carrier properties. The resulting films were characterized via Hall measurements, steady state photoluminescence (SSPL), time resolved PL (TRPL), and external luminescence efficiency measurements (ηₑₓₜ).

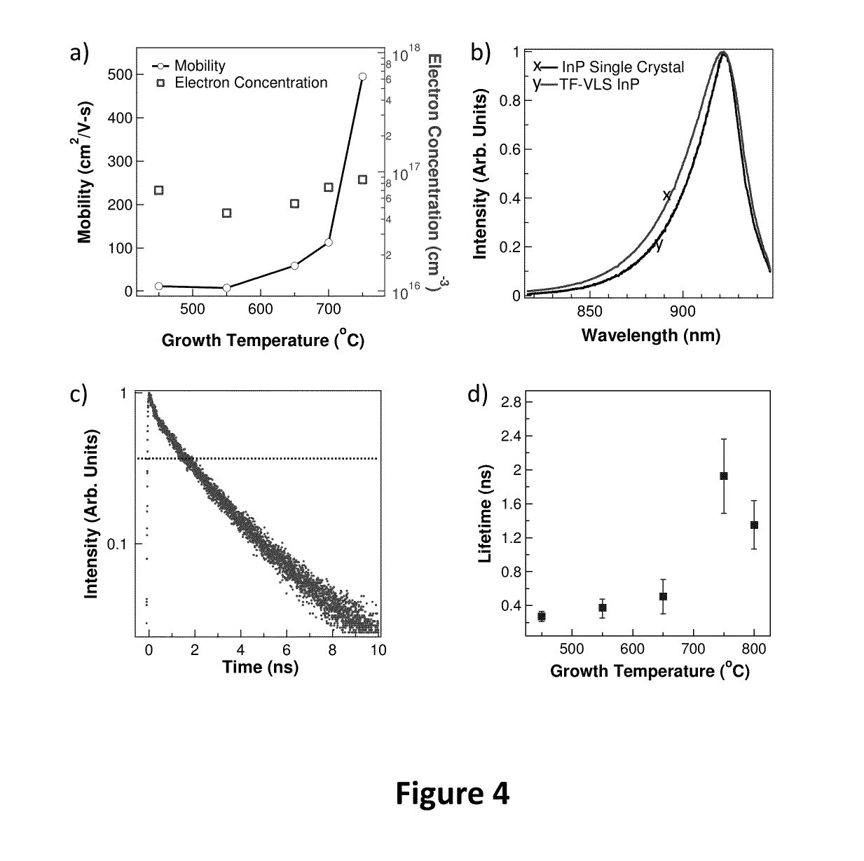

Hall measurements (FIG. 4a) were carried out on InP films peeled off from the Mo substrate to extract carrier concentration and mobility. InP films were found to be n-type with an unintentional doping concentrations between 4 to 8×10¹⁶ cm⁻³, regardless of growth temperature. Notably, this relatively low carrier concentration is obtained without the use of ultrahigh purity Mo foil and indium source. Electron mobility across multiple-grains (over an area of ˜1 cm²), however, exhibits a strong dependence on the growth temperature, increasing from ˜12 cm²/V-s for T_{Growth}=450° C., to ˜500 cm²/V-s for T_{Growth}=750° C. The electron mobility values for the optimal growth temperature approach those of single crystal InP, which range from ˜1500-4000 cm²/V-s depending on doping and compensation ratio.

Micro-SSPL was used to determine (i) the wavelength of the peak photoluminescence intensity, and (ii) the quantum yield of the emission, used to measure the external luminescence efficiency (ηₑₓₜ) an calculate the quasi Fermi level splitting (ΔE_{F}). A representative polycrystalline InP (T_{growth}=750° C.) SSPL curve (y) is shown in FIG. 4b. As a reference, a single crystal n-type InP wafer with a comparable doping concentration (˜3×10¹⁶ cm⁻³) is also plotted (x). A HeNe laser at λ=632.8 nm was used as the excitation source and measurements were performed at ambient temperature. The polycrystalline InP exhibits a SSPL peak position of ˜921.7 nm (1.345 eV) and full width half maximum (FWHM) of ˜37 nm. These measured values are similar to the single crystal reference, which exhibits a peak position of 922.2 nm and a FWHM of 29 nm. TRPL measurements were carried out at room temperature on the polycrystalline InP films to determine the effective minority carrier lifetimes (FIG. 4c). The samples were illuminated with a 800 nm pulsed laser, and the time dependent photoluminescence intensity was recorded at the peak wavelength, as measured by SSPL. FIG. 4d shows the 1/e lifetime as a function of InP growth temperature. The measured effective lifetimes show a clear dependence on the growth temperature, with the InP grown at 450° C. exhibiting the lowest average effective lifetime of ˜0.25 ns, while the films grown at 750° C. exhibit the highest average effective lifetime of ˜2 ns. We hypothesize that at higher temperatures, the InP is more thoroughly annealed during growth, reducing the excess number of point defects and thereby improving the electronic and optoelectronic properties.

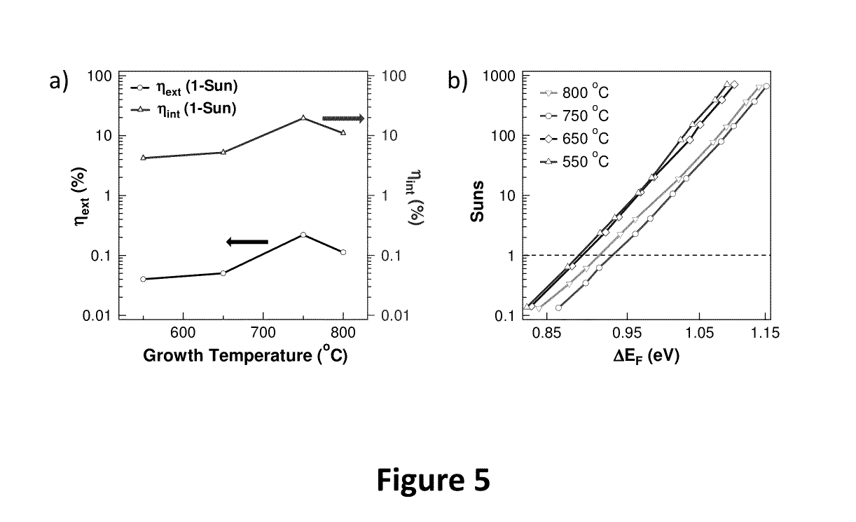

While minority carrier lifetimes offer some insight into the material quality, the key metric for solar cell performance is the open-circuit voltage, V_{OC}. In a semiconductor under illumination, the upper limit for V_{OC} is the difference in the chemical potential between the electron and hole population, defined as the quasi-Fermi level splitting, ΔE_{F}. Thus, extraction of ΔE_{F} allows for a quantitative prediction of the photovoltaic performance limits of a material. ΔE_{F} may be extracted by direct measurement of the external luminescence efficiency, ηₑₓₜ=(number of photons emitted)/(number of photons absorbed), as described in the methods section. The dependence can be qualitatively understood by considering that for a solar cell to reach the Shockley-Quessier (SQ) limit, the only loss mechanism should be radiative recombination. Thus, at the SQ limit under open circuit conditions, one photon must be emitted for each photon absorbed (ηₑₓₜ=100%). The ηₑₓₜ is determined by two factors, the internal luminescence efficiency,ηᵢₙₜ=(radiative recombination rate)/(total recombination rate), and the parasitic optical absorption. From the data obtained by varying incident laser intensity and monitoring the output photoluminescence intensity, we extract the external luminescence efficiency, internal luminescence efficiency, and quasi-Fermi level splitting (FIG. 5). Details of the measurement and analyses are provided in the methods section.

FIG. 5a shows ηₑₓₜ andηᵢₙₜ at 1-sun equivalent power as a function of InP growth temperature. As expected, the trend follows that of the measured minority carrier lifetimes in FIG. 4d, with the luminescence efficiency increasing as the growth temperature up to 750° C. Importantly, the peak ηₑₓₜ is ˜0.2% and vᵢₙₜ is ˜20%. These values compare favorably to other polycrystalline materials used in the state-of-the-art thin film cells, including copper indium gallium selenide (CIGS) and CdTe which exhibit ηₑₓₜ between 0.0001-0.19%^{Error! Bookmark not defined}. It should be possible to further increase the luminesce yields for TF-VLS InP by replacing the Mo foil with a more reflective back contact, while exploring various surface and grain boundary passivation techniques. Nevertheless, the obtained values confirm that TF-VLS growth results in optoelectronic quality InP; quite remarkable considering that the material was grown non-epitaxially on a metal substrate without the use of ultra-high purity materials.

FIG. 5b shows the optically measured “I-V” curves for TF-VLS InP films. Specifically, the incident excitation intensity is plotted versus the extracted quasi-Fermi level splitting (ΔE_{F}) for various growth temperatures (see methods for analyses details). Here, the incident light intensity correlates to the photogenerated current level while ΔE_{F}/q represents the corresponding V_{OC} that would occur to balance the photogenerated current. This technique presents a simple approach for projecting the device performance limit of a given material. The data illustrates that InP samples grown at 750° C. exhibit a high ΔE_{F} of ˜0.93 eV under 1-sun illumination. This extracted ΔE_{F} value is only ˜40 meV lower than that of a single-crystalline InP wafer with a similar unintentional doping concentration (N_{d}=10¹⁶ cm⁻³) measured using the same experimental set-up. Additionally, ΔE_{F} for the TF-VLS InP is higher than those previously reported for CIGS thin films (ΔE_{F}=0.75-0.87 eV)ⁱ. This is an important observation given that the highest efficiency polycrystalline PVs reported to date have been based on CIGS; suggesting favorable performance projection for the TF-VLS InP. Additionally, the inverse slope of the incident light intensity versus ΔE_{F} curves is given as ηln(10)kT, where η is the ideality factor (analogous to that of a diode), k is the Boltzmann's constant and T is the temperature. From the inverse slopes, we obtain η˜1.2 which is close to the ideal limit (where η=1), further suggesting the high optical quality of our material.

In conclusion, the ability to grow InP thin films on metal foils with ultra-large crystallites and material properties approaching those of single crystals presents a route towards low-cost, large-area III-V photovoltaics. Specifically, it should be noted that the TF-VLS process has important advantages in terms of processing costs, especially given the high material utilization yield for indium (which can be electrodeposited) as compared to conventional epitaxial growth processes, such as MOCVD/MOVPE. While in this work, we focused on the use of non-epitaxial metal foil substrates, the TF-VLS process also enables single crystalline film growth with epitaxial substrates. TF-VLS of homoepitaxial single-crystalline thin films of InP has demonstrated. These results demonstrate the versatility of this process for growth on both epitaxial and non-epitaxial substrates. Finally, although InP was utilized as a model system here, this growth technique should be general within the constraints presented here, and may be extended to a variety of other material systems in the future.

### Methods Summary:

InP Growth: InP was grown from starting Mo/In/SiOₓ stacks utilizing a 1-zone furnace with a phosphorus source of 10% PH₃ (99.9995%) in H₂ (99.9999%), or utilizing a 2-zone furnace with a red phosphorus (99.999%) source and H₂ carrier gas. Samples were first heated in a hydrogen environment, followed by exposure to the phosphorus source once the furnace stabilized at the growth temperature. Samples were held at the growth temperature and exposed to the phosphorous source for 20 minutes, followed by cooling (˜20 seconds) to room temperature.

InP Transfer: For certain characterization work, including Hall measurements, InP was peeled from the Mo foil substrate. First, polyimide (PI) was spin coated onto the InP films, followed by thermal curing at 200° C. for 6 hours. Once the PI film was cured, the InP was removed from the Mo foil by mechanical peeling.

Indium Texturing via Langmuir-Blodgett: In order to grow patterned InP, a planar Moan stack was uniformly coated with a monolayer of 1 μm silica beads via a Langmuir-Blodgett process. First, the silica beads were dispersed in DI water; next, the Moan substrate was dipped into suspension and slowly removed. These beads were then mechanically pressed into the underlying indium.

Luminescence Yield: To simulate the response of these materials under varying solar illumination, samples were excited with a HeNe laser (λ=632.8nm) of varying intensity from ˜15 mW/cm² (0.15 suns) to ˜7×10⁴ mW/cm² (700 suns). This intensity represents the absorbed photon flux, calculated by multiplying the incident photon flux by the normal transmission coefficient, separately measured at the laser wavelength. The resulting external luminescence efficiency was calculated by: ηₑₓₜ=(φ_{InP}/φ_{sys})/(φ_{inc}×T) where φ_{inc} and φ_{InP} are the incident HeNe photon flux and the measured InP photon flux, respectively, T is the transmission coefficient at the air/InP boundary as measured via absorption measurements, and η_{sys} is the collection efficiency of the system for a Lambertian reference. Here, the Lambertian reference used was a thick (>3 mm) Spectralon® layer was used as the Lambertian reference.

The internal luminescence efficiency, ηᵢₙₜ is extracted via:

$${η}_{int} = \frac{{η}_{ext} ( 1 + 4 {Ln}^{2} α )}{1 + 4 {Ln}^{2} α {η}_{ext}} \qquad ( 1 )$$

where L is the InP thickness, n is the band-edge refractive index, and α is the band-edge absorption coefficient. It should be noted that Eqn. 1 assumes an ideal back surface minor. In the experimental work, the back surface (i.e., Mo substrate) is a non-ideal minor which provides a loss mechanism for the emitted photons. Thereby, the extracted ηᵢₙₜ values reported here are lower bounds.

The quasi-Fermi level splitting (ΔE_{F}) is calculated by^{Error! Bookmark not defined.}:

$$Δ {E}_{F} = kT ln ( \frac{{R}_{ab s}}{{\int }_{0}^{2 π} {\int }_{0}^{\frac{π}{2}} {\int }_{- ∞}^{∞} a ( E , θ ) b ( E ) cos ( θ ) d E d θ d ∅} ) + kT ln ( {η}_{ext} ) \qquad ( 2 )$$

where R_{abs} is the absorbed photon flux per unit area in the InP, a(E, ⊕) is the absorbance of the semiconductor, and b(E) is the blackbody spectrum at temperature T. The absorbance of the InP was taken to be: a(E, ⊕)=a(E)×T(⊕), where a(E)=1 for E>1.344 eV, and a(E)=0 for E<1.344 eV. This simplifying assumption was made due to the relatively long optical path of the InP films here (3 μm). The angular dependence T(⊕) is the transmission coefficient as determined by the Fresnel equations. The black body spectrum was given by:

$$b ( E ) = \frac{2 {n}^{2}}{{h}^{3} {c}^{2}} {E}^{2} ( \frac{1}{exp ( \frac{E}{kT} ) - 1} )$$

Here, n is the refractive index of air, h is Planck's constant, c is the speed of light, k is the Boltzmann constant, and T=300 K is temperature. It should be noted that since the surface is not truly random, nor flat, the assumption of Fresnel transmission at the top surface adds a small error of ˜5 meV, which is a relative error of 0.5%.

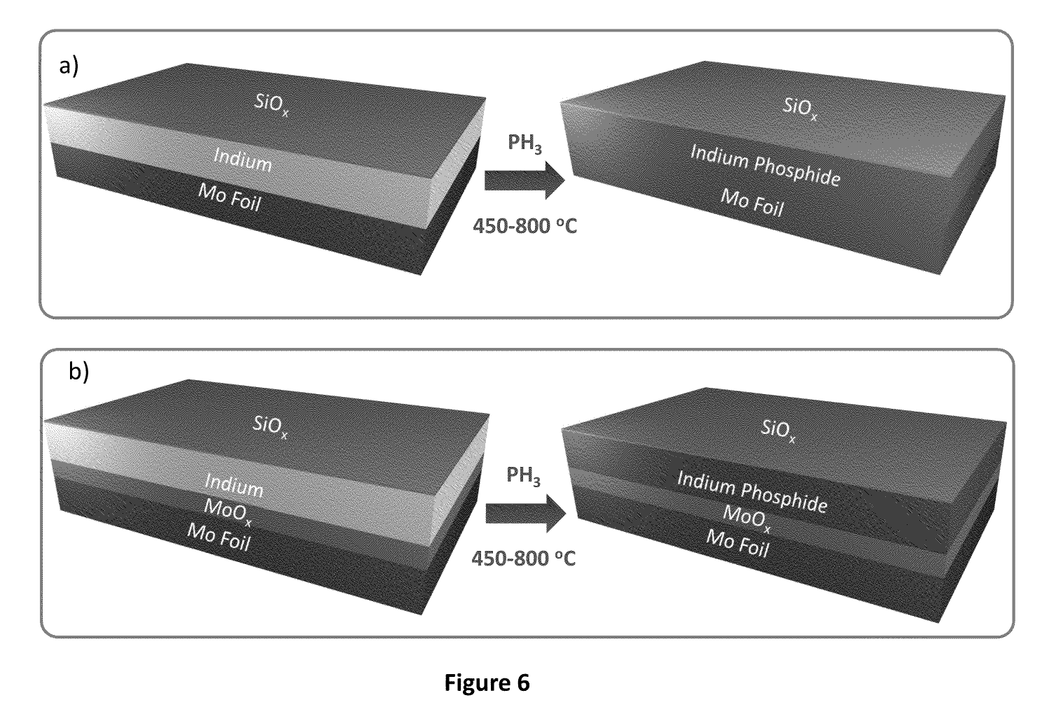

As discussed above, we demonstrated growth of poly-crystalline InP thin films with grain sizes >100 μm on non-epitaxial substrates using the thin-film vapor-liquid-solid (TF-VLS) growth mode. TF-VLS growth occurs by passing the phosphorous precursor gas over an In film, which has been capped with SiOₓ. Phosphorous diffuses through the SiOₓ cap at the growth temperatures, causing supersaturation of the liquid In and inducing precipitation of solid InP. As shown schematically in FIG. 6 and reported previously, the process enables the transformation of an entire In film into InP. The mechanisms that enable TF-VLS growth are (i) the inhibition of In dewetting by the template, comprised of the Mo substrate and SiOₓ capping layer, and (ii) the reduction of incident phosphorous flux by the SiOₓ capping layer, enabling lower nucleation densities.

While similar in concept to the vapor-liquid-solid (VLS) growth mode utilized for nanowire growth the TF-VLS mode enables growth of ultra-large grain continuous thin films, a morphology previously unattainable via the VLS method. Unlike traditional vapor phase growth of polycrystalline materials, TF-VLS growth decouples the lateral nucleation density and film thickness for continuous polycrystalline film growth, enabling lateral grain sizes orders of magnitude larger than film thickness. Due to the large grain sizes, TF-VLS grown polycrystalline InP exhibited optically measured V_{oc} (quasi-Fermi level splitting) ˜95% of single crystalline InP. The near single crystal performance of TF-VLS polycrystalline films suggest that this method could play a key role in future thin film optoelectronic devices.

Due to the extreme sensitivity of optoelectronic device quality to defects such as grain boundaries and interfaces, developing a method for deterministic control of nucleation, in polycrystalline films is of significant interest for device applications. Previously, we showed that nucleation density, and thereby the grain size, in TF-VLS grown films could be controlled by manipulating the phosphorous flux; the nuclei positions, however, were random. Here, we present a general scheme for engineering nucleation in the TF-VLS mode. Specifically, a patterned nucleation promoter (evaporated MoOₓ) is utilized to control the position and density of InP nuclei on Mo foil substrates. Furthermore, a simple model showing quantitative agreement with experiment is presented, leading to a set of design rules for nucleation engineering in TF-VLS grown materials.

The first challenge in designing a process for nucleation engineering is finding two materials, a substrate and nucleation promoter, such that the promoter displays nucleation densities orders of magnitude higher than the substrate. To determine the nucleation density differential between two materials, partial growth of InP films is carried out on both materials under the same conditions. Here, we used Mo foils as the growth substrate and evaporated MoOx thin films as the nucleation promoter layer. The TF-VLS process was explored on Mo foils (25 μm, 99.99%, Alfa Aesar) with (FIG. 6b) and without (FIG. 6a) a thin (50 nm) evaporated MoOₓ layer. Mo foils were first degreased with a single set of consecutive 30 s rinses in acetone, isopropyl alcohol, deionized water and hydrochloric acid. Next, a 1.5 μm thick indium film (99.999%) and a 50 nm SiOₓ (SiO₂ pellets 99.99%, Kurt J. Lesker) capping layer were deposited via consecutive e-beam evaporation steps without breaking vacuum. Phosphorization of the stacks (Mo/In/SiOₓ and Mo/MoOₓ/In/SiOₓ) was carried out in a tube furnace.

For the TF-VLS growth process, the InP films can be quenched in the nucleation, growth or completion stages by varying the growth time. Here, InP films are partially grown and quenched before separate InP crystals coalesce. As a result discrete nucleation sites can be clearly observed, enabling analysis of nucleation density, which dictates the final grain sizes for the fully grown films. The growth was carried out by first heating the substrates in a 1 Torr H₂ ambient to 525° C. followed by phosphorization in a 60 Torr 10% PH₃ ambient for 70 s. The resulting nucleation density is measured by counting the number of independent InP crystals by optical imaging.

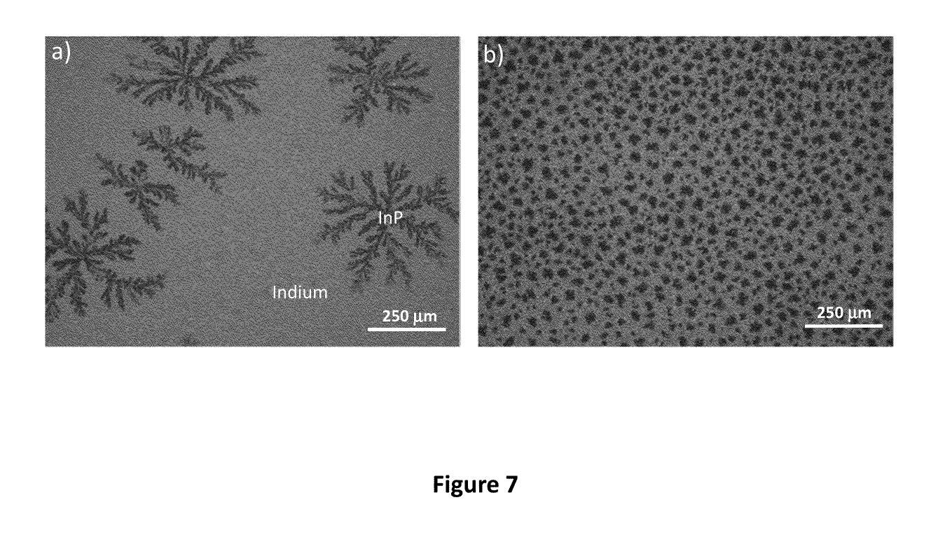

FIG. 7 shows optical images of two samples grown under the same conditions, one on a bare Mo substrate (FIG. 2a) and the other on a Mo/MoOₓ substrate (FIG. 7b). It can clearly be seen that the nucleation density on MoOₓ (FIG. 7b) is much greater than on bare Mo foil (FIG. 7a), suggesting evaporated MoOₓ may serve the role of a nucleation promoter for InP growth. A quantitative nucleation density analysis reveals that the InP nucleation density, N, on the bare Mo substrate is ˜450 cm⁻², while the nucleation density on the MoOₓ is ˜5×10⁴ cm⁻². If we assume hexagonal packing of nuclei, we can define an inter-nuclei length scale,

$$l = {( \frac{8}{3 \sqrt{3}} \frac{1}{N} )}^{0.5} \sim 1.24 / \sqrt{N} ,$$

which corresponds to l_{Mo}=580 μm and l_{MoOx}=55 μm for the bare Mo foil and evaporated MoOₓ, respectively. These numbers subsequently define the limits of nucleation control possible with bare Mo foils and Mo/MoOₓ.

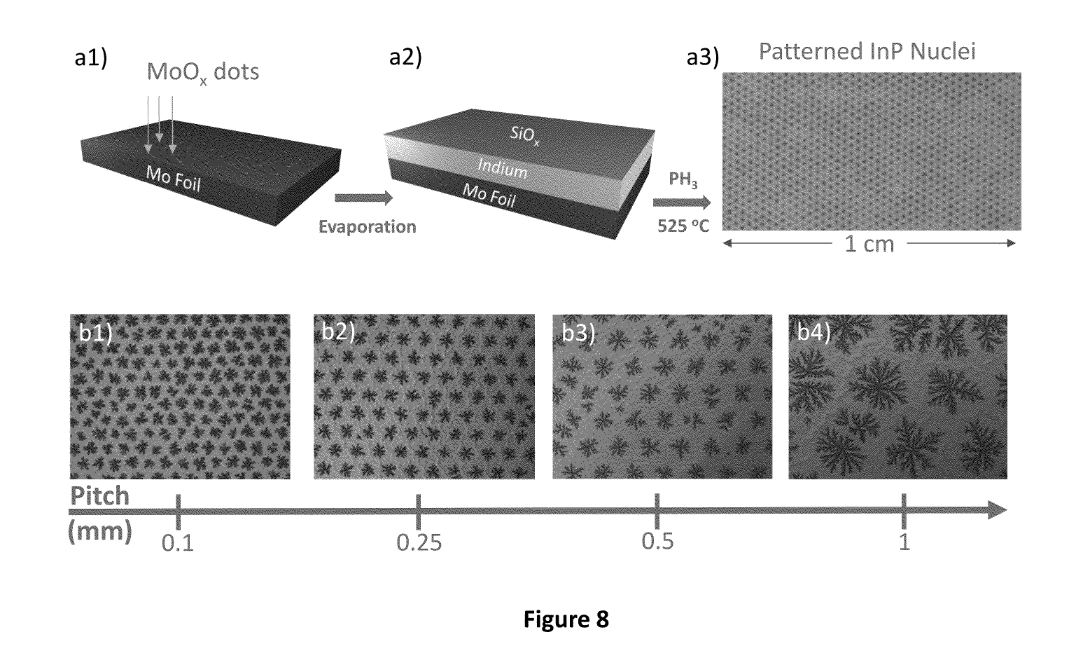

Given that the nucleation density on MoOₓ is two orders of magnitude higher than on Mo foil, we now utilize this disparity to engineer the structure of films on a millimeter scale. First, MoOₓ dots of 10 μm in diameter and 50 nm in thickness were patterned in a regular hexagonal geometry on Mo foils, as shown in FIG. 8—a1. These structures were patterned utilizing a lift-off process. Different pitches of s=0.1, 0.25, 0.5, and 1 mm were used for the MoOₓ dot pattern. Indium and SiOₓ films of 1.5 μm and 50 nm were then evaporated on these heterogeneous Mo/MoOₓ substrates. The resulting substrates are illustrated schematically in FIG. 3—a2.

Next, the films were partially grown at 525° C. for 3 minutes in an ambient of 25 Torr 10% PH₃. This partial growth condition enables sufficient growth of the InP crystals such that they are clearly observable. FIG. 8—a3, shows a 1 cm×0.5 cm optical image of a partially grown sample with 0.25 mm MoOₓ dot pitch, demonstrating that this method can produce uniform patterned nucleation on a centimeter scale, and is limited only by the growth chamber size used here. FIG. 8b shows a set of samples with engineered nucleation position and density of InP crystals with different pitch defined as the spacing between nearest neighbor hexagonal MoOₓ dots. By visual inspection, we see that nucleation occurred on all MoOₓ sites for the various pitches explored here, and as the pitch increases the ratio of nucleation on the MoOₓ sites only to total nucleation

$$( \frac{{N}_{MoOx}}{{N}_{Tot}} )$$

decreases. These observations suggest that (i) the induction time for nucleation on the Mo foil is significantly larger than the induction time for nucleation on the MoOₓ, allowing nucleation on MoOₓ to occur first, and (ii) as MoOₓ pitch increases, a transition from deterministic nucleation to random nucleation occurs but only at very large pitch size, approach 1 mm.

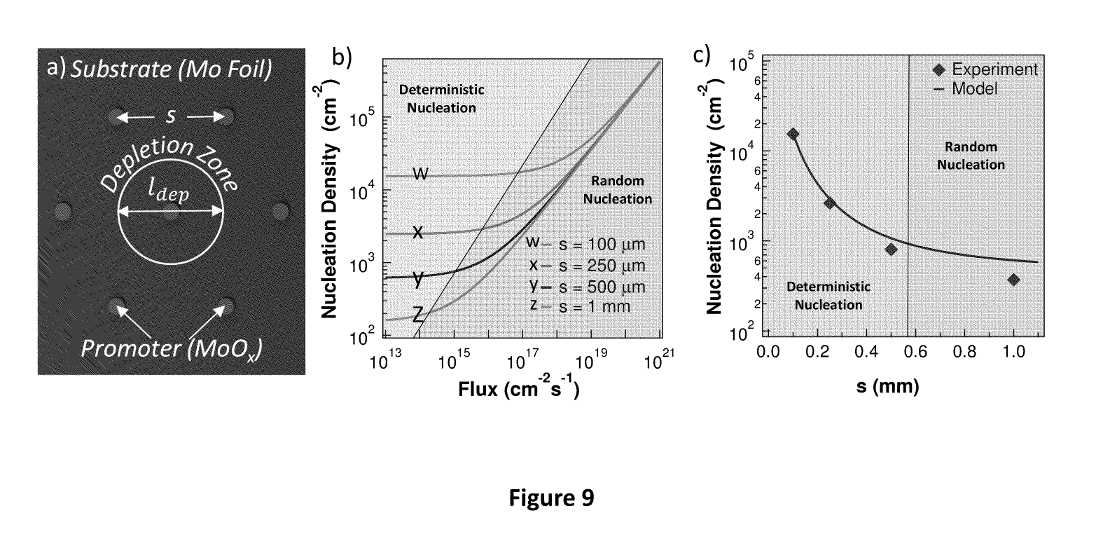

These results may be qualitatively understood by utilizing the concept of the reactant “depletion zone” around growing InP crystals. Specifically, if we assume that the P concentration gradients in the liquid indium relax to the steady state values quickly compared to the timescale for nucleation of InP crystals, then immediately after formation of an InP nucleus, the region surrounding the nucleus will have significantly reduced phosphorous concentrations, preventing further nucleation of InP crystals. We can approximate the length scale of this zone by l_{dep}˜1.24/\sqrt{N} as discussed above. It should be noted that it was previously shown that the nucleation density, and consequently, l_{dep}, are a function of the incident P flux. Specifically, because InP crystals first nucleate on the MoOₓ, a depletion zone surrounds each nucleation promoter site (FIG. 9a). If l_{dep}, which is set by the P flux, is larger than the spacing between nucleation promoters, then effectively all random nucleation will be suppressed on the substrate. Thus, an engineered substrate with patterned arrays of nucleation sites enables user control over the density and position of crystals in the TF-VLS growth mode.

To quantitatively explain the results, we developed a simple model for nucleation on the heterogeneous substrates utilizing a kinetic rate equation approach. Specifically, we modified an approach taken previously, utilizing the assumption that each nucleation promoter site gives rise to a single stable InP nucleus, and that these nucleation events occur before the first nucleation event on the bare Mo foil, allowing us to modify the coupled differential rate equations as follows:

$$\frac{d n}{d t} = \frac{F}{h} - η D {σ}_{1} {n}^{η} - D {σ}_{s} n ( N + {N}_{0} )$$

$$\frac{d N}{d t} = D {σ}_{1} {n}^{η}$$

where F is the net flux of P atoms through the cap (cm⁻²-s⁻¹), h is the height of the initial In film, D is the diffusivity of P in liquid In at the process temperature, σ₁ is the capture coefficient for single P atoms to form an InP nucleus, σₛ is the capture coefficient for stable InP nuclei, n is the excess concentration of P in the liquid In, \acute{η} is the number of P atoms in the critical nucleus, N is the density of stable InP nuclei on the Mo foil, and N₀ is the density of stable InP nuclei on the MoOₓ sites.

It is assumed that (i) the concentration of P achieves steady state,

$$\frac{d n}{d t} = 0 ,$$

and (ii)

ηDσ₁n^{η}<<Dσₛn(N+N₀)

This is a reasonable assumption given our previous calibration to experimental data that shows \acute{η}=4 is the best fit. Since the critical nucleus size is small, and the nucleation density is low, the number of P atoms captured due to nucleation will be much smaller than the number captured by growing stable crystals. Using these approximations, it is possible to solve the coupled rate equations to obtain the solution

$$N = \frac{A}{{h}^{2}} {( \frac{{Fh}^{4}}{D} )}^{α} - {N}_{0} ,$$

where

$$α = \frac{η - 1}{η + 1} ,$$

and is the nucleation density at film completion. Since N≧0, the total nucleation density becomes:

$${N}_{Total} = \{ \begin{matrix}{N}_{0} , & \frac{A}{{h}^{2}} {( \frac{{Fh}^{4}}{D} )}^{α} - {N}_{0} < 0 \\ \frac{A}{{h}^{2}} {( \frac{{Fh}^{4}}{D} )}^{α} , & \frac{A}{{h}^{2}} {( \frac{{Fh}^{4}}{D} )}^{α} - {N}_{0} \geq 0\end{matrix}$$

This can be approximated by the smooth function

$${N}_{Total} \sim \frac{A}{{h}^{2}} {( \frac{{Fh}^{4}}{D} )}^{α} + {N}_{0} ,$$

since for most incident fluxes either

$$\frac{A}{{h}^{2}} {( \frac{{Fh}^{4}}{D} )}^{α} ≫ {N}_{0} or \frac{A}{{h}^{2}} {( \frac{{Fh}^{4}}{D} )}^{α} ≪ {N}_{0} .$$

When the two terms are similar, the maximum error will be a factor of 2. Furthermore, this equation will be valid when the (i) density of MoOₓ nucleation sites, N₀, is less than the nucleation density on a planar MoOₓ film, and (ii) the nucleation on the MoOₓ sites occurs before nucleation on the Mo substrate.

The model predicts two regimes, (i) the deterministic nucleation regime, where nucleation occurs entirely on the nucleation promoter sites, and (ii) the random nucleation regime, where nucleation occurs on both the promoter sites and the bare substrate. Since l_{dep} is a function of incident flux, it is expected that the cross-over between deterministic and random nucleation occurs at different flux values depending on the pitch of the patterned promoter dots. FIG. 9b shows a plot of N_{Total} as a function of incident flux for different promoter pitches using previously calibrated values for A and α. The curves for each pitch show the two nucleation regimes as a function of flux, with the cross-over flux decreasing as pitch is increased. Similarly, FIG. 4c shows the nucleation density as a function of pitch at a constant flux, a situation which corresponds to the experimental series presented in FIG. 8b. By extracting the flux for the experimental growth conditions, we can plot the expected nucleation density as a function of pitch and compare those values to experiment. The flux is extracted using a procedure previously reported and found to be ˜7×10¹⁵ cm⁻² s⁻¹. As shown in FIG. 9c, both experiment and theory are in good accord, further validating the nucleation mechanism proposed here.

In conclusion, we have demonstrated a simple method to control nuclei position and nucleation density of InP films grown via the TF-VLS growth mode. Critically, we show that it is possible to obtain millimeter scale inter-nuclei spacing and precise control over nucleation position. This corresponds to grain sizes approaching millimeter scale for fully grown thin films on non-epitaxial substrates, which is an incredible observation. Furthermore, we show that a characteristic length, set by the substrate nucleation density demarcates the boundary between the promoter nucleation and random nucleation regimes and may be used as a design parameter for other material systems and growth conditions. As grain boundaries are often a primary cause of carrier loss in polycrystalline devices, the ability to deterministically position grains in continuous, polycrystalline thin films offers an unprecedented level of control over the non-epitaxially grown film structure. In the future, this method could be leveraged such that each device falls on a single millimeter scale grain, enabling a polycrystalline material to appear as a single crystal material from a device perspective.

What we claim is:

1. A solar cell comprising;
a substrate;
a polycrystalline III-V semiconductor layer disposed above the substrate; and
an oxide layer disposed above the polycrystalline III-V semiconductor layer.

2. The solar cell of claim 1 wherein the substrate is a metal.

3. The solar cell of claim 2 wherein the substrate is Molybdenum (Mo).

4. The solar cell of claim 2 wherein the substrate is Aluminum (Al) or Tungsten (W).

5. The solar cell of claim 1 wherein the oxide layer is silicon oxide (SiOₓ), wherein x=0, 1, or 2.

6. The solar cell of claim 1 wherein the polycrystalline III-V semiconductor layer comprises at least one of grain sizes greater than 200 microns, minority carrier lifetimes >2 ns, and hall mobilities of >500 cm̂2/V-s.

7. The solar cell of claim 1 wherein the polycrystalline III-V semiconductor layer is Indium Phosphide (InP).

8. The solar cell of claim 1 wherein the polycrystalline III-V semiconductor layer is selected from the group consisting of Indium Phosphide (InP), Indium Arsenide (InAs), Indium Nitride (InN), Indium Antimonide (InSb), Gallium Phosphide (GaP), Gallium Arsenide (GaAs), Gallium Nitride (GaN), Gallium Antimonide (GaSb), Boron Nitride (BN), Boron Phosphide (BP), Boron Arsenide (BAs), Aluminum Nitride (AlN), Aluminum Phosphide (AlP), Aluminum Arsenide (AlAs), Aluminum Antimonide (AlSb).

9. The solar cell of claim 1 wherein polycrystalline III-V semiconductor layer is formed utilizing a thin-film (TF) vapor-liquid-solid (VLS) deposition.

10. A method of making a composition comprising;
providing a substrate;
depositing a group III element semiconductor layer on the substrate; and
depositing an oxide layer on the group III semiconductor layer;
heating the oxide layer, the group III semiconductor layer, and substrate; and
exposing the oxide layer and the group III semiconductor layer to a group V semiconductor vapor to complete a thin-film (TF) vapor-liquid-solid (VLS) deposition.

11. The method of claim 10 wherein the substrate is a metal.

12. The method of claim 11 wherein the substrate is Molybdenum (Mo).

13. The method of claim 11 wherein the substrate is Aluminum (Al) or Tungsten (W).

14. The method of claim 10 wherein the polycrystalline III-V semiconductor layer comprises at least one of grain sizes greater than 200 microns, minority carrier lifetimes >2 ns, and hall mobilities of >500 cm̂2/V-s.

15. The method of claim 10 wherein the oxide layer is silicon oxide (SiOₓ), wherein x=0, 1, or 2.

16. The method of claim 10 wherein the polycrystalline III-V semiconductor layer is Indium Phosphide (InP).

17. The method of claim 10 wherein the polycrystalline III-V semiconductor layer is selected from the group consisting of Indium Phosphide (InP), Indium Arsenide (InAs), Indium Nitride (InN), Indium Antimonide (InSb), Gallium Phosphide (GaP), Gallium Arsenide (GaAs), Gallium Nitride (GaN), Gallium Antimonide (GaSb), Boron Nitride (BN), Boron Phosphide (BP), Boron Arsenide (BAs), Aluminum Nitride (AlN), Aluminum Phosphide (AlP), Aluminum Arsenide (AlAs), Aluminum Antimonide (AlSb).

18. The method of claim 10 wherein the substrate/Group III semiconductor layer oxide layer is heated in hydrogen to a growth temperature of between 450-800° C.

19. The method of claim 10 wherein a polycrystalline III-V semiconductor layer is formed utilizing the thin-film (TF) vapor-liquid-solid (VLS) deposition.

20. A composition comprising;
a substrate;
a polycrystalline III-V semiconductor layer disposed above the substrate; and
an oxide layer disposed above the polycrystalline III-V semiconductor layer.

21. The composition of claim 20 wherein the substrate is a metal.

22. The composition of claim 21 wherein the substrate is Molybdenum (Mo).

23. The composition of claim 21 wherein the substrate is Aluminum (Al) or Tungsten (W).

24. The composition of claim 20 wherein the oxide layer is silicon oxide (SiOₓ), wherein x=0, 1, or 2.

25. The composition of claim 20 wherein the polycrystalline III-V semiconductor layer is selected from the group consisting of Indium Phosphide (InP), Indium Arsenide (InAs), Indium Nitride (InN), Indium Antimonide (InSb), Gallium Phosphide (GaP), Gallium Arsenide (GaAs), Gallium Nitride (GaN), Gallium Antimonide (GaSb), Boron Nitride (BN), Boron Phosphide (BP), Boron Arsenide (BAs), Aluminum Nitride (AlN), Aluminum Phosphide (AlP), Aluminum Arsenide (AlAs), Aluminum Antimonide (AlSb).

26. The composition of claim 20 wherein the polycrystalline III-V semiconductor layer is Indium Phosphide (InP).

27. The composition of claim 20 wherein polycrystalline III-V semiconductor layer is formed utilizing a thin-film (TF) vapor-liquid-solid (VLS) deposition.

28. The composition of claim 20 wherein polycrystalline III-V semiconductor layer comprises grain sizes between 100-200 microns.

29. The composition of claim 20 wherein polycrystalline III-V semiconductor layer comprises grain sizes greater than 200 microns.

30. The composition of claim 20 wherein polycrystalline III-V semiconductor layer comprises minority carrier lifetimes >2 ns.

31. The composition of claim 20 wherein polycrystalline III-V semiconductor layer comprises hall mobilities of >500 cm̂2/V-s.
